(19) United States
(12) Patent Application Publication
(10) Pub. No.: US 2023/0292462 A1
(43) Pub. Date: Sep. 14, 2023

(54) HEAT SINK BASE AND HEAT SINK

(71) Applicant: BEIJING DEEPCOOL INDUSTRIES CO., LTD., Beijing (CN)

(72) Inventors: Dangsheng ZHAO, Beijing (CN); Yan LI, Beijing (CN); Yaojia LOU, Beijing (CN); Heng LI, Beijing (CN); Edward XIA, Beijing (CN); Yijia DING, Beijing (CN); Lucas LU, Beijing (CN)

(73) Assignee: BEIJING DEEPCOOL INDUSTRIES CO., LTD., Beijing (CN)

(21) Appl. No.: 18/184,795

(22) Filed: Mar. 16, 2023

Related U.S. Application Data
(63) Continuation of application No. PCT/CN2022/073384, filed on Jan. 24, 2022.

(30) Foreign Application Priority Data
Jan. 13, 2022 (CN) 202210039348.6

(51) Int. Cl. H05K 7/20

(52) U.S. Cl. CPC H05K 7/20254; H05K 7/20436; H05K 7/20136; H05K 7/20272; H05K 7/20409; H05K 7/20518

(57) ABSTRACT

Disclosed are a heat sink base and a heat sink. The heat sink base includes a base body. The bottom of the base body is provided with at least one protruded structure, and the bottom of the base body abuts against the top of the CPU. Each of the at least one protruded structure includes a gentle region with a protrusion, and a slope region surrounding the protruded gentle region with the protrusion. The gentle region of the protruded structure abuts against a high heat flux region at the top of the CPU, thus forming a region with relatively high pressure and relatively stable pressure compared with the slope region. Therefore, the heat sink base provided by the present invention has a simple and reasonable structure, and can efficiently dissipate the heat generated by the CPU, thus improving the cooling efficiency and obtaining more stable and more consistent cooling performance.

### CROSS-REFERENCE TO RELATED APPLICATIONS

The application claims priority to Chinese patent application No. 202210039348.6, filed on Jan. 13, 2022, the entire contents of which are incorporated herein by reference.

### FIELD OF TECHNOLOGY

The present disclosure relates to the technical field of CPU (central processing unit) cooling, and in particular to a heat sink base and a heat sink.

### BACKGROUND

With the development of electronic information technology, the computing power of CPU is becoming more and more powerful, accompanied by the increase of its heat generation and the increasing requirements for cooling.

As shown in FIG. 1-1 and FIG. 1-2, the general structure of CPU is usually composed of several parts, including the circuit board with contacts or pins, chip and other devices, and metal (copper) cover. The heat generation of CPU is mainly generated by the operation of the chip, and a relatively high heat flux is formed on the surface of the chip as the area of the chip is small. Usually, the copper cover on the surface of CPU is internally connected to the chip by heat-conductive silicone grease or metal brazing layers, which, in addition to playing a protective role, can diffuse the heat emitted by the chip with small area through the conduction of copper cover to form larger heating area on the surface of the copper cover, so as to form a better secondary cooling effect after abutting against the heat sink. However, as the heat conductivity, density and specific heat capacity of the copper are limited, as shown in FIG. 2, the temperature on the surface of the copper cover of CPU is non-uniform, the temperature distribution is that the temperature is distributed outwards from high to low by taking the internal chip as the center, so that a relative high heat flux region is also formed on the surface of the copper cover. The chips (chipsets) of CPU can be physically gathered together or dispersed into multiple (groups).

A lot of heat is generated when the CPU operates, the heat needs to be dissipated in time, otherwise may greatly affect the operation the CPU and shorten the service life of the CPU. To guarantee the effective cooling of CPU during operation, a heat sink with higher cooling efficiency is required to provide secondary cooling, which is usually called a CPU heat sink. The power consumption is increasing with the increase in computing power of CPU, the CPU heat sink have evolved from initial pure metal heat sinks, metal heat sinks with air cooling, to the current heat-pipe air-cooled heat sinks and water-cooled heat sinks. No matter what form of heat sink, it is necessary to have a base. Heat-conductive interface materials, such as heat-conductive silicone grease, are coated between the surface of heat sink base and the surface of CPU to fill the gap caused by the difference of flatness or roughness between the two surfaces. The surface of the heat sink base and the surface of CPU are connected together in a contact manner by applying a certain pressure through special fasteners, that is, to play a stable fixed role; moreover, the heat-conductive silicone grease can also be extended and thinned as much as possible by applying pressure to reduce thermal contact resistance and improve cooling efficiency.

From the bottom form of the heat sink base, as shown in FIG. 3, there are two more common designs for the bottom forms of CPU heat sink bases in the industry: a flat bottom and a tapered convex bottom. The design thought of the flat bottom is to make heat sink base in close contact with the surface of CPU to achieve the least thermal contact resistance and better cooling effect. The original intention of the tapered convex bottom design is as follows: due to the fact that the power consumption of the early CPU is low, the CPU chip is small in size and located in the center of the CPU, and the contact between the CPU chip and the copper cover on its surface is that the non-solid heat-conductive silicone grease is filled inside, the bottom surface of the heat sink base is machined into a tapered form, which forms a continuous slope towards the edge with the center of the bottom surface as the highest point, by a special machining process, greater pressure can be formed above the chip via the clamping force of the fastener pressure, and through the extrusion force conducted by the stress, the grease between the copper cover above the chip and the internal chip can form a thinner interface layer to further reduce thermal contact resistance and enhance the cooling effect. However, with the improvement of CPU process, the chip and the copper cover are connected by using metal brazing process in more advanced CPU at present, so such an extrusion effect on the silicon grease inside the copper cover no longer exists. However, this effect is also applicable to the heat-conductive silicone grease coated on the contact surface between the bottom of heat sink base and the outer surface of the copper cover of CPU, so the tapered convex bottom is still a common bottom form of heat sink base at present.

However, in the engineering practice of testing the performance of multiple CPU samples of the same model, no matter what base bottom form in the prior art is adopted, the single heat sink still has the problem of great difference in test performance of different CPU samples of the same specification, and the test results reflected by some test cases even directly affect the effectiveness of the cooling products, so such results inevitably directly affect the consistent performance of product performance.

The information disclosed in this background art is merely intended to increase the understanding of the general background of the present invention, and should not be taken as an admission or any form of suggestion that this information constitutes the prior art that is known to those skilled in the art.

### SUMMARY

An objective of the present disclosure is to find out the reasons for the great difference and low consistency of the test performance of the same heat sink for different CPU individuals through in-depth research, and to provide a heat sink base and a heat sink. Therefore, more stable and more consistent cooling performance can be achieved in the test and use of different CPU individuals of the same model, and the product performance can be further improved.

At first, through the precise measurement of multiple CPU samples of the same model, it is found that there is a difference of surface flatness between the CPU individuals, as shown in Table 1:

TABLE 1
Reference measurement data of surface
flatness of sample CPU (unit: mm)

| CPU | | X axle- | | Y axle- |
|---|---|---|---|---|
| sample | X axle- | central | Y axle- | central |
| number | edge | point | edge | point |
| 1 | 0 | 0.04 | 0 | 0.02 |
| 2 | 0 | 0.02 | 0 | 0.01 |
| 3 | 0 | 0.02 | 0 | 0.015 |
| 4 | 0 | 0.02 | 0 | 0.01 |
| 5 | −0.015 | −0.000 | 0.1 | 0 |
| 6 | −0.015 | −0.005 | 0.1 | −0.01 |
| 7 | −0.01 | −0.01 | 0.01 | −0.005 |
| 8 | 0.02 | 0 | 0.01 | −0.005 |
| 9 | 0 | 0.02 | 0 | 0.01 |
| 10 | 0 | 0.02 | 0 | 0.015 |
| 11 | 0 | 0.03 | 0 | 0.02 |

The flatness difference shown in Table 1 may be reflected more intuitively by constructing example models as shown in FIGS. 4-1 and 4-2, and finally can be summarized into three specific forms of CPU surfaces as shown in FIG. 5, i.e., slightly convex center, high flatness, and slightly concave center.

Although CPU is an industrial product with high precision, the differences in surface flatness may also be caused due to different machining methods and technological levels, and it is precisely because of these small differences that different form types are formed on the CPU surface.

Afterwards, by summarizing and analyzing the test data of flat-bottom and tapered convex-bottom heat sinks in the prior art on different CPU individuals according to different surface form types of CPU, it is found that a strong correlation is formed between the performance of a particular heat sink and its adopted base bottom form as well as the surface form of the correspondingly adapted CPU, as shown in FIG. 6.

Heat sink samples in the test all employ uniform specifications of heat-conductive silicone grease, heat pipes, cooling fin groups and base materials, and consistent processing and assembly technology, the fastener pressure is ensured to be uniform, and the only difference factor is the bottom surface form of the heat sink base. Therefore, it can be inferred that the difference between the bottom surface of the heat sink base and the surface of the CPU is the fundamental reason for the great difference of final cooling performance.

Thermal interface materials, such as heat-conductive silicone grease, need to be filled between the bottom surface of the heat sink base and the surface of CPU, which is an important part affecting thermal contact resistance. Taking the heat-conductive silicon grease as an example, the heat-conductive silicon grease is a non-solid compound, and has excellent ductility under the action of the pressure. As the heat-conductive interface material filled between the top surface of the CPU and the bottom surface of the heat sink base is generally extruded and stretched particularly thin under the action of the fastener pressure, the size of the heat-conductive interface material in a thickness direction is much less than that in two horizontal directions, and the temperature change in the thickness direction is much greater than that in other two horizontal directions. Therefore, the heat transfer through the interface material can be simplified into a one-dimensional steady-state heat conduction problem, and thermal resistance R of the interface material layer may be expressed as:

$$R = \frac{δ}{λ A}$$

where δ is a thickness of the interface material, λ is a thermal conductivity of the interface material, and A is the contact area between the interface material and the top surface of the CPU. The smaller the δ, the greater the λ or A, and thus the smaller thermal contact resistance R, the better the cooling performance.

In addition, as shown in FIG. 2, the temperature distribution on the surface of the CPU is non-uniform, leading to the existence of a region with a relatively high heat flux. If the lowest thermal contact resistance is achieved at this region, the cooling effect can be maximized.

As shown in FIG. 6 and FIG. 7, by analyzing the adaptation characteristics of the flat bottom and tapered convex bottom in the prior art with the CPU with different surface forms one by one, and combining with the actual test data, the reasons for the performance difference can be well explained, specifically as follows:

(1) Adaption of the Flat-Bottom Heat Sink to a CPU with Slightly Concave Surface:

A gap is formed between the bottom of the flat-bottom heat sink and the slightly concave part on the surface of the CPU, the pressure at the gap is smaller than that at the surrounding region, resulting in a large silicon grease thickness δ, and the position is the central position of the CPU as shown in FIG. 4-1, which is just the region with high heat flux of the test sample CPU, so the cooling performance is poor.

(2) Adaption of the Tapered Convex-Bottom Heat Sink to the CPU with Slightly Concave Surface:

As the tapered convex structure at the center position of the heat sink can fill the gap caused by the depression of the surface of the CPU, and even form relatively high pressure at the high heat flux region of the CPU to make the silicon grease thickness δ relatively small. Meanwhile, as the slightly concave surface of the CPU is similar to the tapered convex bottom form of the heat sink, a certain high-pressure contact area A can be formed at the high heat flux region on the surface of the CPU, and then better cooling effect can be obtained.

(3) Adaption of the Flat-Bottom Heat Sink to a CPU with High Flatness:

The above adaption relationship is the most ideal situation, the pressure distribution on the whole contact interface is relatively uniform to ensure relatively small heat-conductive interface material thickness δ and relatively large contact area A, so the cooling performance is good.

(4) Adaption of the Tapered Convex-Bottom Heat Sink to the CPU with High Flatness:

As the tapered convex-bottom heat sink forms large pressure at the high heat flux region of the CPU, the interface material thickness δ smaller than that in (3) is formed to make up for the disadvantages that the high-pressure contact area A is relatively small, so the cooling performance is close to that of above (3) in which the flat-bottom heat sink adapts to the CPU with high flatness.

(5) Adaption of the Flat-Bottom Heat Sink to a CPU with Slightly Convex Surface:

As a protruded region of the CPU with slightly convex surface is a high heat flux region of the CPU (as shown in FIG. 2), and the protruded part is a region with a certain area (as shown in FIG. 4-2), a region with a certain area A and a smaller interface material thickness δ can be formed at the high heat flux region in this adaptation combination, and therefore this adaptation relationship can obtain the relatively optimal cooling performance.

(6) Adaption of the Tapered Convex-Bottom Heat Sink to the CPU with Slightly Convex Surface:

Although the high heat flux density region of the CPU in this adaptation relationship may form extremely high pressure at the center of the corresponding tapered convex bottom, which in turn forms a small interface material thickness δ, the performance in this adaptation relationship is relatively worst because the area of the high-pressure region A is tiny due to the rapid decay of the pressure from the center to the periphery caused by characteristics of fitting forms.

From the above analysis, it can be seen that in the bottom surface design of the heat sink base in the prior art, the CPU is preset to have a surface with high flatness, without considering thermal contact resistance difference caused by the surface flatness and form difference of the CPU, which inevitably leads to the problems of large performance difference and poor consistency. Meanwhile, better cooling performance is hard to obtain as the above problems are neglected.

Due to the fact that CPU, as an industrial product, has subtle differences that are difficult to unify in its surface form, two types of the bottom surface form designs for the base commonly used in the prior art always lead to the problem that some users can achieve the cooling design performance in use while others cannot, ultimately resulting in poor consistency in the application effect of the heat sink, but the consistency of the cooling performance is just one of the key indicators to measure the quality of industrial products.

In addition, with the continuous improvement of CPU performance, the heating power consumption is gradually improved, and the heat flux of the heating core is also gradually increased. Due to the limitation of the bottom design for the base in the prior art, it is difficult to meet the demand of further improving the cooling performance of the heat sink.

To solve the problem above, it is necessary to design a bottom structure of a heat sink base according to a brand-new idea, which can satisfy the requirements that high pressure can be formed at the high heat flux region at the center of the corresponding CPU in the process of abutting against and adapting to different form types of CPU, and then a smaller interface material thickness S can be obtained. Meanwhile, the position and area A of the high-pressure region can be preset, i.e., the high pressure in the high-pressure region is stable and effective in a certain area range, and the high-pressure region can adapt to the cooling demands of different types of CPU with different high beat flux characteristics through area setting. Therefore, higher performance consistency and better average cooling performance can be achieved.

In a first aspect, the present invention provides a heat sink base, including a base body. The bottom of the base body is provided with at least one protruded structure, and the bottom of the base body abuts against the top of a CPU. Each of the at least one protruded structure includes a gentle region with a protrusion, and a slope region surrounding the gentle region with the protrusion. The gentle region of the protruded structure abuts against a high heat flux region at the top of the CPU, thus forming a region with relatively high pressure and relatively stable pressure compared with the slope region.

In an embodiment of the present invention, the gentle region of the protruded structure is located on an internal region of the protruded structure, and a projection of the slope region is located on two sides of a projection of the gentle region.

In an embodiment of the present invention, the gentle region of the protruded structure is located on an internal region of the protruded structure, and a projection of the slope region is located on three sides of a projection of the gentle region.

In an embodiment of the present invention, the gentle region of the protruded structure is located on an internal region of the protruded structure, and a projection of the slope region is located on the periphery of a projection of the gentle region.

In an embodiment of the present invention, the height of a geometric center point of the gentle region of the protruded structure is greater than or equal to that of the edge of the region; and on a contour line of either side of a horizontal direction of any profile passing through the geometric center point, an absolute value of a vertical height difference corresponding to a unit horizontal distance of any local range in the gentle region is smaller than an absolute value of a vertical height difference corresponding to a unit horizontal distance of any local range in the slope region.

In an embodiment of the present invention, the center of the gentle region of the protruded structure abuts against the center of the high heat flux region at the top of the CPU, thus forming a region with relatively high pressure and relatively stable pressure compared with the slope region.

In an embodiment of the present invention, the center of the gentle region of the protruded structure abuts against the position close to the center of the high heat flux region at the top of the CPU, thus forming a region with relatively high pressure and relatively stable pressure compared with the slope region.

In an embodiment of the present invention, the projection area of the gentle region of the protruded structure is smaller than the area of the top of the CPU.

In an embodiment of the present invention, a projection form of the gentle region of the protruded structure is circular.

In an embodiment of the present invention, a projection form of the gentle region of the protruded structure is elliptic.

In an embodiment of the present invention, a projection form of the gentle region of the protruded structure is polygonal.

In an embodiment of the present invention, a profile contour line of a gentle region part of the protruded structure is a straight line.

In an embodiment of the present invention, a profile contour line of a gentle region part of the protruded structure is an arc line.

In an embodiment of the present invention, a profile contour line of a gentle region part of the protruded structure is a broken line.

In an embodiment of the present invention, the area of the gentle region of the protruded structure is 20 mm² to 254 mm².

In an embodiment of the present invention, the area of the gentle region of the protruded structure is 20 mm² to 177 mm².

In an embodiment of the present invention, the area of the gentle region of the protruded structure is 20 mm² to 113 mm².

In an embodiment of the present invention, the area of the gentle region of the protruded structure is 20 mm² to 79 mm.

In an embodiment of the present invention, the area of the gentle region of the protruded structure is 20 mm² to 50 mm.

In a second aspect, the present invention provides a heat sink, configured to cool a CPU. The heat sink includes a base body. The bottom of the base body is provided with at least one protruded structure, and the bottom of the base body abuts against the top of a CPU; each of the at least one protruded structure includes a gentle region with a protrusion and a slope region located on the periphery of the gentle region. The gentle region of the protruded structure abuts against a high heat flux region at the top of the CPU, thus forming a region with relatively high pressure and relatively stable pressure compared with the slope region.

In an embodiment of the present invention, the gentle region of the protruded structure is located on an internal region of the protruded structure, and a projection of the slope region is located on two sides of a projection of the gentle region.

In an embodiment of the present invention, the gentle region of the protruded structure is located on an internal region of the protruded structure, and a projection of the slope region is located on three sides of a projection of the gentle region.

In an embodiment of the present invention, the gentle region of the protruded structure is located on an internal region of the protruded structure, and a projection of the slope region is located on the periphery of a projection of the gentle region.

In an embodiment of the present invention, the height of a geometric center point of the gentle region of the protruded structure is greater than or equal to that of the edge of the region, and on a contour line of either side of a horizontal direction of any profile passing through the geometric center point, an absolute value of a vertical height difference corresponding to a unit horizontal distance of any local range in the gentle region is smaller than an absolute value of a vertical height difference corresponding to a unit horizontal distance of any local range in the slope region.

In an embodiment of the present invention, the center of the gentle region of the protruded structure abuts against the center of the high heat flux region at the top of the CPU, thus forming a region with relatively high pressure and relatively stable pressure compared with the slope region.

In an embodiment of the present invention, the center of the gentle region of the protruded structure abuts against the position close to the center of the high heat flux region at the top of the CPU, thus forming a region with relatively high pressure and relatively stable pressure compared with the slope region.

In an embodiment of the present invention, the projection area of the gentle region of the protruded structure is smaller than the area of the top of the CPU.

In an embodiment of the present invention, a projection form of the gentle region of the protruded structure is circular.

In an embodiment of the present invention, a projection form of the gentle region of the protruded structure is elliptic.

In an embodiment of the present invention, a projection form of the gentle region of the protruded structure is polygonal.

In an embodiment of the present invention, a profile contour line of a gentle region part of the protruded structure is a straight line.

In an embodiment of the present invention, a profile contour line of a gentle region part of the protruded structure is an arc line.

In an embodiment of the present invention, a profile contour line of a gentle region part of the protruded structure is a broken line.

In an embodiment of the present invention, the area of the gentle region of the protruded structure is 20 mm² to 254 mm².

In an embodiment of the present invention, the area of the gentle region of the protruded structure is 20 mm² to 50 mm².

In an embodiment of the present disclosure, the heat sink further includes: a cooling fin group, a heat pipe group, a cooling fan, heat-conductive silicon grease, and a fixing assembly. The cooling fin group is arranged at one end away from the base body. The heat pipe group includes at least one heat pipe; each of the heat pipes includes a heat adsorption section and a cooling section, the heat adsorption section is arranged on the base body, and the cooling section is arranged in the cooling fin group. The cooling fan is fixed to the cooling fin group. The heat-conductive silicone grease is arranged between the base body and the surface of the CPU. The fixing assembly is configured to fix the base body to the position above the CPU

In an embodiment of the present invention, the heat sink may not be provided with the cooling fan, or may be provided with a plurality of cooling fans.

In an embodiment of the present disclosure, the heat sink further includes: a cooling part, a heat absorption part, and a pipeline part. The cooling part is provided with a water inlet and a water outlet. The heat adsorption part is provided with a water inlet and a water outlet, a water pump is arranged inside the heat adsorption part, and the heat adsorption part is arranged on one end of the base body. The pipeline part includes a first pipeline and a second pipeline, one end of the first pipeline and one end of the second pipeline are connected to the water inlet and the water outlet of the cooling part, respectively; and the other end of the first pipeline and the other end of the second pipeline are connected to the water outlet and the water inlet of the heat adsorption part, respectively; and under the action of the water pump, cooling liquid circulates among the cooling part, the pipeline part and the heat absorption part.

Firstly, by designing the protruded gentle region, when adapting to the different forms of CPU, similar pressure characteristics can be formed in the range of the preset area of the gentle region, then the similar interface material thickness δ can be obtained, and the similar thermal contact resistance is also obtained. Compared with the prior art, more consistent cooling performance can be obtained. Secondly, due to the features of the protruded structure, the pressure at the gentle region is high, and the area can be guaranteed through the arrangement of the gentle region. Therefore, the smaller average interface material thickness δ can be obtained in a determined range, and the smaller average thermal contact resistance is obtained. Meanwhile, as the protruded gentle region corresponds to the high heat flux region on the surface of the CPU, the better cooling effect can be obtained.

Compared with the prior art, the heat sink base and the heat sink according to the present invention have a simple and reasonable structure, can better adapt to the CPU with different surface forms, can obtain more stable and more consistent cooling performance, and can efficiently dissipate the heat energy generated by the CPU, so as to improve the cooling efficiency.

### BRIEF DESCRIPTION OF THE DRAWINGS

FIG. 1-1 is a schematic diagram of an axial structure of an existing CPU;

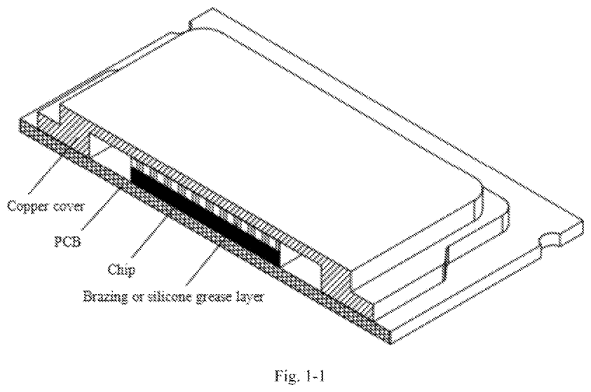

FIG. 1-2 is a schematic diagram of a profile structure of an existing CPU;

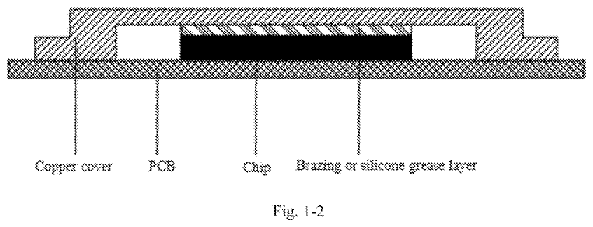

FIG. 2 is a schematic diagram of temperature distribution on the surface of an existing CPU of model Y;

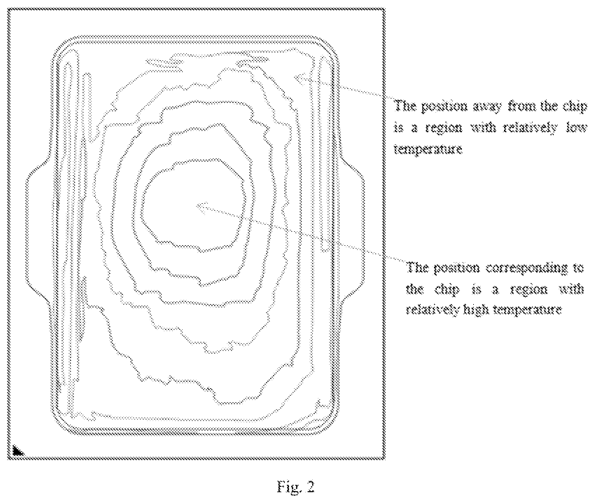

FIG. 3 is a schematic diagram of profile forms of two heat sink bases in the prior art;

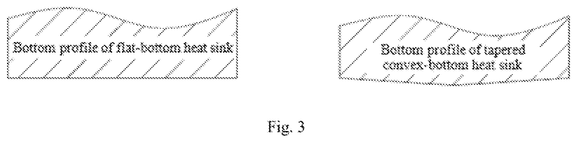

FIG. 4-1 is a schematic diagram of a top contour line of an existing CPU with slightly concave surface of model X:

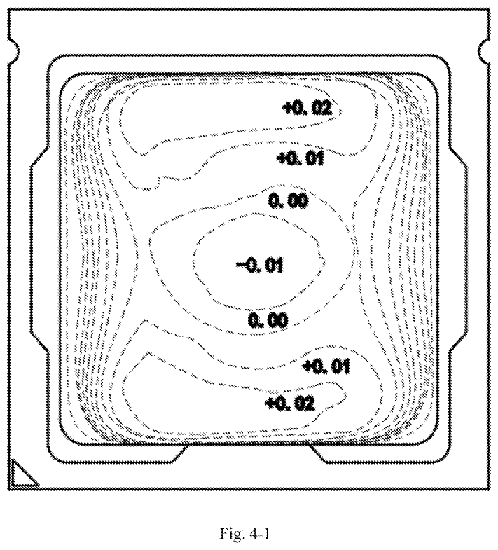

FIG. 4-2 is a schematic diagram of a top contour line of an existing CPU with slightly convex surface of model X;

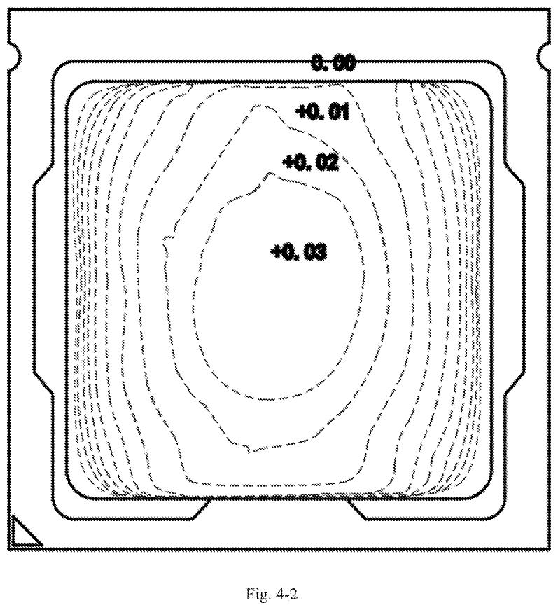

FIG. 5 is a schematic diagram of profiles of existing CPU with three surface forms;

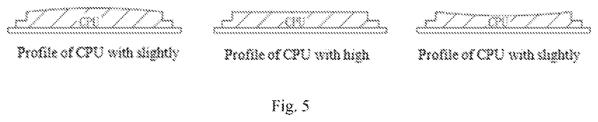

FIG. 6 shows performance test data of two heat sink bases in the prior art on CPU with different surface forms;

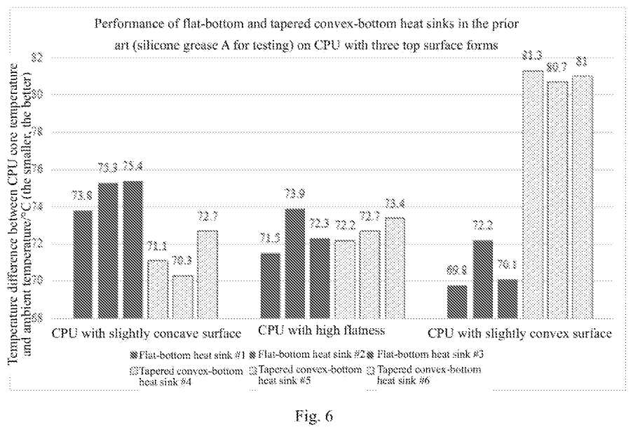

FIG. 7 is a schematic diagram of adaptation characteristics of a heat sink base in the prior art to the surface of a CPU;

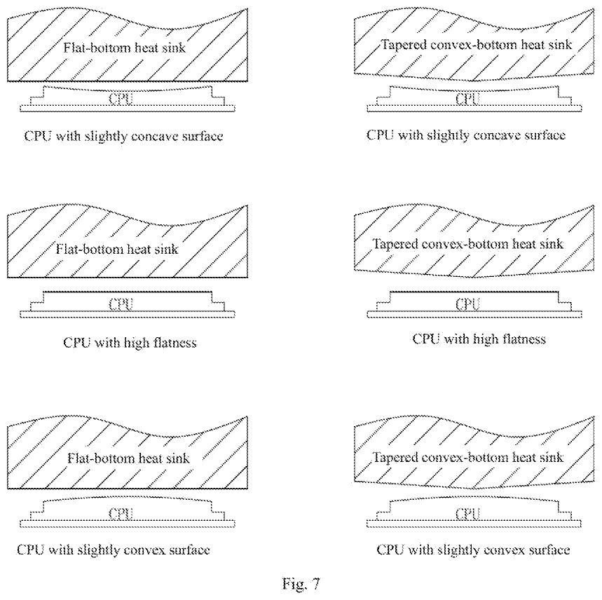

FIG. 8 is a schematic diagram of a certain profile passing through the center point of a gentle region in accordance with an embodiment of the present invention;

FIG. 9 is a schematic structure diagram of a heat sink base and a heat sink in accordance with an embodiment of the present invention;

FIG. 10 is another schematic structure diagram of a heat sink base and a heat sink in accordance with an embodiment of the present invention;

FIG. 11 is a schematic diagram of three example characteristics of a profile contour line of a gentle region part of a protruded structure in accordance with an embodiment of the present invention;

FIG. 12 is a schematic diagram showing the performance of a heat sink base as well as a #2 module of a heat sink with four types of different bottoms in accordance with an embodiment of the present invention on a CPU with slightly concave surface;

FIG. 13 is a schematic diagram showing the performance of a heat sink base as well as a #2 module of a heat sink provided with four types of different bases in accordance with an embodiment of the present invention on a CPU with high flatness;

FIG. 14 is a schematic diagram showing the performance of a heat sink base as well as a #2 module of a heat sink provided with four types of different bases in accordance with an embodiment of the present invention on a CPU with slightly convex surface;

FIG. 15 is a schematic diagram showing the performance of a heat sink base as well as a #4 module of a heat sink provided with four types of different bases in accordance with an embodiment of the present invention on a CPU with slightly concave surface;

FIG. 16 is a schematic diagram showing the performance of a heat sink base as well as a #4 module of a heat sink provided with four types of different bases in accordance with an embodiment of the present invention on a CPU with high flatness;

FIG. 17 is a schematic diagram showing the performance of a heat sink base as well as a #4 module of a heat sink provided with four types of different bases in accordance with an embodiment of the present invention on a CPU with slightly convex surface:

FIG. 18 is a schematic diagram showing the positional relationship between a projection of a gentle region and a projection of a slope region in accordance with an embodiment of the present invention;

FIG. 19 is a schematic diagram showing a projection form of a gentle region part of a protruded structure in accordance with an embodiment of the present invention.

In the drawings:

1—base body; 11—protruded structure; 111—gentle region; 112—slope region; 2—cooling fin group: 3—heat pipe group; 4—cooling fan; 5—heat absorption part; 6—cooling part.

### DESCRIPTION OF THE EMBODIMENTS

Specific embodiments of the present invention are described in detail below with reference to the accompanying drawings, but it should be understood that the scope of protection of the present invention is not limited by the specific embodiments.

Unless otherwise expressly stated, throughout the specification and claims, the term “including” or its variations such as “containing” or “comprising” may be understood as including the stated elements or components, but not excluding other elements or components.

In a first aspect, a heat sink according to a preferred embodiment of the present invention includes a base body 1. The bottom of the base body 1 is provided with at least one protruded structure 11, the bottom of the base body 1 abuts against the top of a CPU, and each of the at least one protruded structure 11 includes a gentle region 111 with a protrusion, and a slope region 112 surrounding the gentle region 111. The gentle region 111 is located inside the protruded structure 11, and the slope region 112 is located on the periphery of the gentle region 111. The gentle region 111 of the protruded structure 11 abuts against a high heat flux region at the top of the CPU, thus forming a region with relatively high pressure and relatively stable pressure compared with the slope region 112.

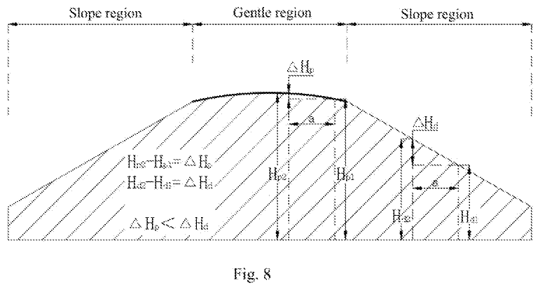

As shown in FIG. 8, the height of a geometric center point of the gentle region 111 is greater than or equal to that of the edge of the region, and on a contour line of either side of a horizontal direction of any profile passing through the geometric center point, an absolute value ΔHₚ of a vertical height difference corresponding to a unit horizontal distance a of any local range in the gentle region 111 is smaller than an absolute value ΔH_{d} of a vertical height difference corresponding to a unit horizontal distance a of any local range in the slope region 112. i.e., ΔHₚ is less than ΔH_{d}. The gentle region 111 of the protruded structure 11 corresponds to the high heat flux region at the top of the CPU, thus forming a region with relatively high pressure and relatively stable pressure compared with the slope region 112. where ΔHₚ=|Hₚ₂−Hₚ₁|, Hₚ₂ is a vertical height of one pint in the gentle region 111, Hₚ₁ is a vertical height of another point in the gentle region 111, and a spacing distance between the two points is the unit horizontal distance a. where ΔH_{d}=|H_{d2}−H_{d1}|, H_{d2} is a vertical height of one pint in the slope region 112, H_{d1} is a vertical height of another point in the slope region 112, and a spacing distance between the two points is the unit horizontal distance a.

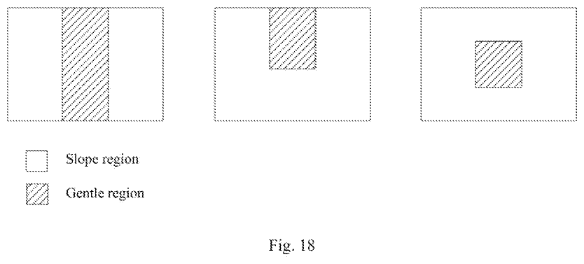

As shown in FIG. 18, the gentle region 111 of the protruded structure 11 is located on an internal region of the protruded structure 11, and a projection of the slope region 112 is located on two sides of a projection of the gentle region 111.

As shown in FIG. 18, the gentle region 111 of the protruded structure 11 is located on an internal region of the protruded structure 11, and a projection of the slope region 112 is located on three sides of a projection of the gentle region 111.

As shown in FIG. 18, the gentle region 111 of the protruded structure 1l is located on an internal region of the protruded structure 11, and a projection of the slope region 112 is located on the periphery of a projection of the gentle region 111.

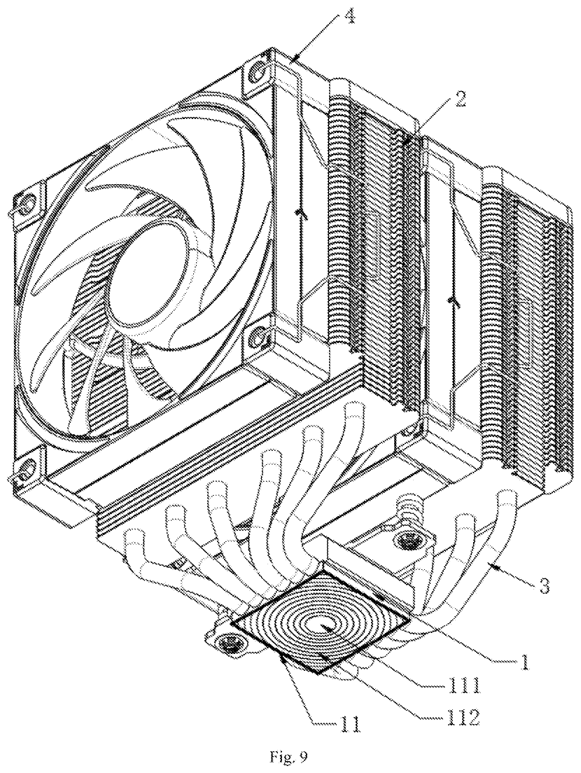

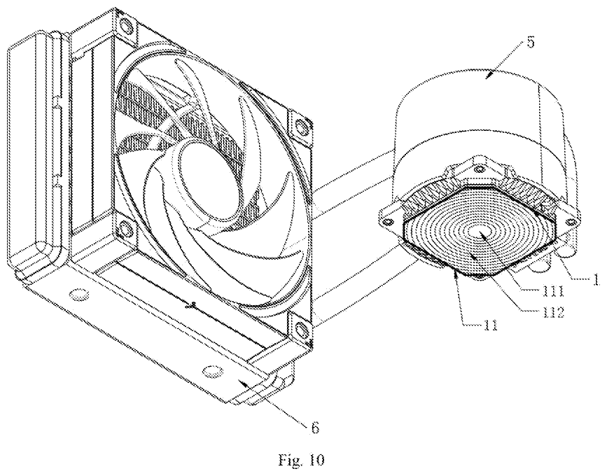

In an embodiment of the present invention, the center of the gentle region 111 of the protruded structure 11 abuts against the center of the high heat flux region at the top of the CPU or the position close to the center of the high heat flux region at the top of the CPU, thus forming a region with relatively high pressure and relatively stable pressure compared with the slope region 112. That is, the center of the gentle region 111 abuts against the center of the high heat flux region at the top of the CPU or the position close to the center above. As shown in FIG. 9 and FIG. 10, the gentle region 111 is located inside the protruded structure 11, but the position of the gentle region 111 is not limited in the present invention. The gentle region 111 may be located on other positions of the bottom of the base body 1 (not shown in figure specifically), as long as the center of the gentle region 111 abuts against with the center of the high heat flux region at the top of the CPU or the position close to the center above. That is, the specific position of the high heat flux region at the top of the CPU is also not limited in the present invention.

In an embodiment of the present invention, the projection area of the gentle region 111 of the protruded structure 11 is smaller than the area of the top of the CPU.

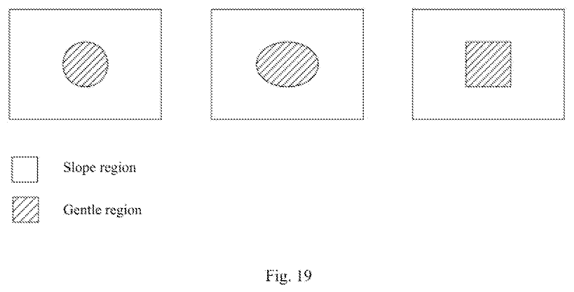

As shown in FIG. 19, in an embodiment of the present invention, a projection form of the gentle region 111 of the protruded structure 11 is circular.

As shown in FIG. 19, in an embodiment of the present invention, a projection form of the gentle region 111 of the protruded structure 11 is elliptic.

As shown in FIG. 19, in an embodiment of the present invention, a projection form of the gentle region 111 of the protruded structure 11 is polygonal.

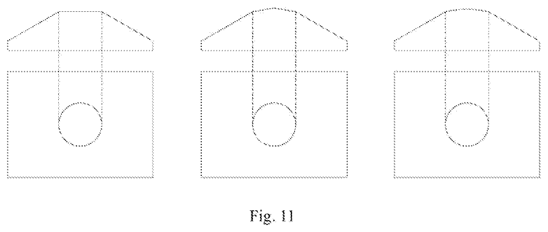

FIG. 11 is a schematic diagram of three example characteristics of the gentle region 111 of the protruded structure 1I at the bottom of the heat sink in accordance with an embodiment of the present invention. As shown in FIG. 11, when the projection form of the gentle region 111 is circular, the profile contour line of the gentle region 111 includes a straight line, an arc line or a broken line. Three different forms of gentle regions 111 correspondingly adapt to the high heat flux region at the top of the CPU.

In an embodiment of the present invention, the area of the gentle region 111 of the protruded structure 11 is 20 mm² to 254 mm².

In an embodiment of the present invention, the area of the gentle region 111 of the protruded structure 11 is 20 mm² to 177 mm².

In an embodiment of the present invention, the area of the gentle region 111 of the protruded structure 11 is 20 mm² to 113 mm².

In an embodiment of the present invention, the area of the gentle region 111 of the protruded structure 11 is 20 mm² to 79 mm².

In an embodiment of the present invention, the area of the gentle region 111 of the protruded structure 11 is 20 mm² to 50 mm².

In a second aspect, a heat sink according to another embodiment of the present invention is configured to cool a CPU. The heat sink includes a base body 1. The bottom of the base body 1 is provided with at least one protruded structure 11, the bottom of the base body 1 abuts against the top of a CPU, and each of the at least one protruded structure 11 includes a gentle region 111 with a protrusion, and a slope region 112 surrounding the gentle region 111. The gentle region is located inside the protruded structure 11, and the slope region 112 is located on the periphery of the gentle region 111. The gentle region 111 of the protruded structure 11 abuts against a high heat flux region at the top of the CPU, thus forming a region with relatively high pressure and relatively stable pressure compared with the slope region 112.

In an embodiment of the present invention, as shown in FIG. 8, the height of a geometric center point of the gentle region 111 is greater than or equal to that of the edge of the region, and on a contour line of either side of a horizontal direction of any profile passing through the geometric center point, an absolute value ΔHₚ of a vertical height difference corresponding to a unit horizontal distance a of any local range in the gentle region 111 is smaller than an absolute value ΔH_{d} of a vertical height difference corresponding to a unit horizontal distance a of any local range in the slope region 112. i.e., ΔHₚ is less than ΔH_{d}. The gentle region 111 of the protruded structure 11 corresponds to the high heat flux region at the top of the CPU, thus forming a region with relatively high pressure and relatively stable pressure compared with the slope region 112. where ΔHₚ=|Hₚ₂−Hₚ₁|, Hₚ₂ is a vertical height of one pint in the gentle region 111, Hₚ₁ is a vertical height of another point in the gentle region 111, and a spacing distance between the two points is the unit horizontal distance a. where ΔH_{d}=|H_{d2}−H_{d1}|, H_{d2} is a vertical height of one pint in the slope region 112, H_{d1} is a vertical height of another point in the slope region 112, and a spacing distance between the two points is the unit horizontal distance a.

As shown in FIG. 18, the gentle region 111 of the protruded structure 11 is located on an internal region of the protruded structure 11, and a projection of the slope region 112 is located on two sides of a projection of the gentle region 111.

As shown in FIG. 18, the gentle region 111 of the protruded structure 11 is located on an internal region of the protruded structure 11, and a projection of the slope region 112 is located on three sides of a projection of the gentle region 111.

As shown in FIG. 18, the gentle region 111 of the protruded structure 11 is located on an internal region of the protruded structure 11, and a projection of the slope region 112 is located on the periphery of a projection of the gentle region 111.

In an embodiment of the present invention, the center of the gentle region 111 of the protruded structure 11 abuts against the center of the high heat flux region at the top of a CPU or the position close to the center of the high heat flux region at the top of the CPU, thus forming a region with relatively high pressure and relatively stable pressure compared with the slope region 112. That is, the center of the gentle region 111 abuts against the center of the high heat flux region at the top of the CPU or the position close to the center above. As shown in FIG. 9 and FIG. 10, the gentle region 111 is located inside the protruded structure 11, but the position of the gentle region 111 is not limited in the present invention. The gentle region 111 may be located on other positions of the bottom of the base body 1 (not shown in figure specifically), as long as the center of the gentle region 111 abuts against with the center of the high heat flux region at the top of the CPU or the position close to the center above. That is, the specific position of the high heat flux region at the top of the CPU is also not limited in the present invention.

In an embodiment of the present disclosure, as shown in FIG. 9, the heat sink further includes: a cooling fin group 2, a heat pipe group 3, and a cooling fan 4. The cooling fin group 2 is arranged above the base body 1. The heat pipe group 3 includes a plurality of heat pipes, where each heat pipe includes a heat adsorption section and a cooling section, the heat adsorption section is arranged on the base body 1, and the cooling section is arranged in the cooling fin group 2. The cooling fan 4 is fixed to the cooling fin group 2. Heat-conductive silicone grease is arranged between the base body 1 and the CPU. The fixing assembly is configured to fix the base body 1 to the position above the CPU. In other embodiments of the present invention, the heat sink may not be provided with the cooling fan, or may be provided with a plurality of cooling fans.

In an embodiment of the present disclosure, as shown in FIG. 10, the heat sink further includes: a cooling part 6, a heat absorption part 5, and a pipeline part. The cooling part 6 is provided with a water inlet and a water outlet. The heat adsorption part 5 is provided with a water inlet and a water outlet, a water pump is arranged inside the heat adsorption part 5, and the heat adsorption part 5 is arranged on one end of the base body 1. The pipeline part includes a first pipeline and a second pipeline, one end of the first pipeline and one end of the second pipeline are connected to the water inlet and the water outlet of the cooling part 6, respectively; and the other end of the first pipeline and the other end of the second pipeline are connected to the water outlet and the water inlet of the heat adsorption part 5, respectively; and under the action of the water pump, cooling liquid circulates among the cooling part 6, the pipeline part and the heat absorption part 5.

In an embodiment of the present invention, the projection area of the gentle region 111 of the protruded structure 11 is smaller than the area of the top of the CPU.

As shown in FIG. 19, in an embodiment of the present invention, a projection form of the gentle region 111 of the protruded structure 11 is circular.

As shown in FIG. 19, in an embodiment of the present invention, a projection form of the gentle region 111 of the protruded structure 11 is elliptic.

As shown in FIG. 19, in an embodiment of the present invention, a projection form of the gentle region 111 of the protruded structure 11 is polygonal.

In an embodiment of the present invention, a profile contour line of a gentle region 111 part of the protruded structure 11 is a straight line.

In an embodiment of the present invention, a profile contour line of a gentle region 111 part of the protruded structure 11 is an arc line.

In an embodiment of the present invention, a profile contour line of a gentle region 111 part of the protruded structure 11 is a broken line.

In an embodiment of the present invention, the area of the gentle region 111 of the protruded structure 11 is 20 mm² to 254 mm².

In an embodiment of the present invention, the area of the gentle region 111 of the protruded structure 11 is 20 mm² to 177 mm².

In an embodiment of the present invention, the area of the gentle region 111 of the protruded structure 11 is 20 mm² to 113 mm².

In an embodiment of the present invention, the area of the gentle region 111 of the protruded structure 11 is 20 mm² to 79 mm².

In an embodiment of the present invention, the area of the gentle region 111 of the protruded structure 11 is 20 mm² to 50 mm².

The physical characteristics of the heat sink is that any protruded structure 11 includes a gentle region 111, and a slope region 112 corresponding to the gentle region 111. The gentle region 111 is located on the internal region of the protruded structure 11, and the slope region 112 is located on the periphery of the gentle region 111. In the gentle region 111, the height of the geometric center point of the region is greater than or equal to that of the edge of the region, and on a contour line of either side of a horizontal direction of any profile passing through the geometric center point, an absolute value of a vertical height difference corresponding to a unit horizontal distance of any local range in the gentle region 111 is smaller than an absolute value of a vertical height difference corresponding to a unit horizontal distance of any local range in the slope region 112. As the flat region 11I is the top region of the protruded structure 11, larger pressure may be formed when the flat region 111 abuts against the surface of the CPU. Moreover, the height change in the unit horizontal distance in the gentle region 111 is less than that in the slope region 112, so the pressure change in the gentle region 111 is less than that of the peripheral slope region 112. FIG. 11 shows the form characteristics of the gentle region in three embodiments of the patent technology.

In actual application, the differences in the surface forms of the CPU in reality have been discovered through in-depth study. By combining the internal and external structural characteristics, the heat generation mechanism and the technical development trend of the CPU, the test results of adaptation performance of different heat sink bottom forms and CPU with different surface characteristics are analyzed by cross comparison with the measured data of a large number of experimental samples, and a brand-new heat sink base bottom design structure with a region with stable and high pressure is creatively designed, which is described as follows.

It is noted in the present invention that there is a specific region range for both the temperature gradient characteristics formed on the surface of the CPU chip due to heat generation and the measured convex-concave deformation characteristics of the surface form of CPU, and the two types of regional ranges have high coincidence. Therefore, a protruded gentle region 111 with specified area is designed at the bottom of the heat sink base for the region (high heat flux region) corresponding to the position of the internal chip of the corresponding CPU, which can better adapt to the CPU with different surface forms to form a region with relatively high pressure and relatively stable pressure. In this region, the pressure is larger but the pressure change is smaller, and outside this region is the slope region 112, which is smaller in pressure but larger in pressure change. In the range of the gentle region 111 with a certain set area of protrusion, the design enables the formation of similar pressure characteristics within the range of the preset area of the gentle region 111 when adapting to the CPU with different form, the similar interface material thickness δ is obtained, and the similar thermal contact resistance is obtained, and thus the more consistent cooling performance can be obtained compared with the prior art. Secondly, due to the features of the protruded structure, the pressure at the gentle region 111 is relatively high, and the area can be guaranteed through the arrangement of the gentle region 111. Therefore, the smaller average interface material thickness δ can be obtained in a determined range, and the small average thermal contact resistance is obtained. Meanwhile, due to the fact that the protruded gentle region 111 corresponds to the high heat flux region on the surface of the CPU, better cooling effect can be obtained.

The advantages and performance of the present invention are presented mainly from two dimensions:

1. More consistent and more stable performance can be obtained on a CPU with one or several surface forms than in the prior art.

2. More comprehensive performance can be obtained on a CPU with one or several surface forms than in the prior art.

The above advantages and performance of the present invention are illustrated by the test analysis of a specific embodiment below.

(1) CPU samples with three top surface forms: X is a CPU of a certain model, with super-frequency power consumption up to 280 w. Eleven CPU of this specification are selected randomly, and it is found that the surface forms of the CPU are as follows: three CPU are slightly concave in surface, one CPU is high in surface flatness, and seven CPU are slightly convex in surface, one is selected from each of the three types of CPU as the CPU used in the test;

(2) Replacement of the bases of the samples with bases with different bottom forms: a total of six heat pipe fin groups are provided in the test, which are divided into two sample groups, and respectively marked as a #1, #2 and #3 heat pipe fin group, and a #4, #5 and #6 heat pipe fin group. No any change is made to the heat pipe fin group each time the heat sink base is replaced. The combination of each heat pipe fin group and its matching base is shown in Table 2.

TABLE 2
The matching combination of six heat pipe
fin sets and their matching copper bases

| | | First | Second | Third |
|---|---|---|---|---|
| | | replacement | replacement | replacement |
| | Initial base | of base | of base | of base |
| #1, #2 and #3 heat | Flat base | Aₛₜₚ = | Aₛₜₚ = | Aₛₜₚ = |
| pipe fin group | | 177 mm² | 113 mm² | 254 mm² |
| #4, #5 and #6 heat | Tapered | Aₛₜₚ = | Aₛₜₚ = | Aₛₜₚ = |
| pipe fin group | convex base | 79 mm² | 50 mm² | 20 mm² |

In the table, Aₛₜₚ refers to the projection area of the gentle region 111 of the protruded structure 11 of the base.

By taking the #1 heat pipe fin group as an example, an initial operation is to weld a flat base, and after the test is completed, the flat base is subjected to back-welding, then a base with Aₛₜₚ=177 mm² is welded; and above action is repeated to replace the base with a base with Aₛₜₚ=113 mm² as well as a base with Aₛₜₚ=254 mm². For the other five samples, the base replacement operation and test are carried out according to this method, so as to obtain the samples representing different gentle region 111 area as well as test data.

(3) Test conditions: Every time samples with different bases are obtained, the samples are tested on CPU with three surface forms. Test equipment is provided strictly and uniformly from beginning to end, and the experimental environment temperature is controlled at 23° C. to 25° C. Uniform specifications of heat-conductive silicone grease, heat pipes, cooling fin groups, base materials and consistent processing and assembly technology are adopted for testing, and the consistent fastener pressure value is guaranteed.

The advantages of the present invention are described below in conjunction with the test data and charts.

Firstly, the present invention is obtained on the basis of pioneering research on the adaption relationship between the surface form of a CPU and the bottom of a heat sink base. Therefore, compared with the prior art, the application of the present invention can enable the heat sink to obtain more stable and more consistent cooling performance when adapting to CPU with different surface forms, thus greatly improving the reliability of products.

Table 3 is the performance of three sample groups on a CPU with slightly concave surface, the three sample groups are a flat base sample group, a tapered convex base sample group, and a sample group with Aₛₜₚ=50 mm² in the present invention. There are three samples in each sample group, and the average performance is an average value of the test performance of the three samples, and the standard deviation and range are used to characterize the discrete characteristics and performance consistency of the samples in the sample group. It can be known from the data that the sample group with Aₛₜₚ=50 mm² obtains more stable and more consistent cooling performance is obtained in the performance test of adapting to the CPU with slightly concave surface, and meanwhile, the average performance of the sample group with Aₛₜₚ=50 mm² is also superior to that of two sample groups in the prior art.

TABLE 3
Performance of three sample groups on the CPU with CPU with
slightly concave surface (silicon grease B for testing)

| | Performance of | | | |
|---|---|---|---|---|
| | three samples in | | | |
| | each sample | Average | Standard | |
| | group/° C. | performance/° C. | deviation/° C. | Range/° C. |
| Flat base sample group | 70.3 | 70.6 | 0.35 | 0.7 |
| | 71 | | | |
| | 70.6 | | | |
| Tapered convex base | 69.4 | 69.6 | 0.68 | 1.3 |
| sample group | 69.1 | | | |
| | 70.4 | | | |
| Sample group with | 67.5 | 67.5 | 0.10 | 0.2 |
| Aₛₜₚ = | 67.4 | | | |
| 50 mm² | 67.6 | | | |
| in the present invention | | | | |

Table 4 shows the performance of the three sample groups on a CPU with high flatness, it can be known from the data that the sample group with Aₛₜₚ=50 mm² obtains more stable and more consistent cooling performance is obtained in the performance test of adapting to the CPU with high flatness, and meanwhile, the average performance of the sample group with Aₛₜₚ=50 mm² is also superior to that of two sample groups in the prior art.

TABLE 4
Performance of three sample groups on the CPU with
high flatness (silicon grease B for testing)

| | Performance of | | | |
|---|---|---|---|---|
| | three samples in | | | |
| | each sample | Average | Standard | |
| | group/° C. | performance/° C. | deviation/° C. | Range/° C. |
| Flat base sample group | 68.3 | 69.2 | 0.78 | 1.5 |
| | 69.8 | | | |
| | 69.4 | | | |
| Tapered convex base | 68.4 | 68.9 | 1.01 | 1.8 |
| sample group | 68.3 | | | |
| | 70.1 | | | |
| Sample group with | 66.3 | 66.5 | 0.20 | 0.4 |
| Aₛₜₚ = | 66.5 | | | |
| 50 mm² | 66.7 | | | |
| in the present invention | | | | |

Table 5 shows the performance of the three sample groups on a CPU with slightly convex surface, it can be known from the data that the sample group with Aₛₜₚ=50 mm² obtains more stable and more consistent cooling performance in the performance test of adapting to the CPU with slightly convex surface, and meanwhile, the average performance of the sample group with Aₛₜₚ=50 mm² is also superior to that of two sample groups in the prior art.

TABLE 5
Performance of three sample groups on the CPU with slightly
convex surface (silicon grease B for testing)

| | Performance of | | | |
|---|---|---|---|---|
| | three samples in | | | |
| | each sample | Average | Standard | |
| | group/° C. | performance/° C. | deviation/° C. | Range/° C. |
| Flat base sample group | 68.6 | 69.3 | 0.70 | 1.4 |
| | 70 | | | |
| | 69.2 | | | |
| Tapered convex base | 71.3 | 71.8 | 1.14 | 2.1 |
| sample group | 71 | | | |
| | 73.1 | | | |
| Sample group with | 68.0 | 67.7 | 0.26 | 0.5 |
| Aₛₜₚ = | 67.6 | | | |
| 50 mm² | 67.5 | | | |
| in the present invention | | | | |

By summarizing the content in Table 3, Table 4 and Table 5, it can be known from the data that the sample group with Aₛₜₚ=50 mm² obtains more stable and more consistent cooling performance in the performance test of adapting to the CPU with slightly concave surface, the CPU with high flatness, and the CPU with slightly convex surface, and meanwhile, the average performance of the sample group with Aₛₜₚ=50 mm² is also superior to that of two sample groups in the prior art.

Table 6 shows the performance of the three sample groups on three types of CPU, it can be known from the data that the sample group with Aₛₜₚ=50 mm² obtains more stable and more consistent cooling performance in the performance test of adapting to three types of CPU with different surface forms, and meanwhile, the average performance of the sample group with Aₛₜₚ=50 mm² is also superior to that of two sample groups in the prior art.

TABLE 6
Summary of performance of three sample groups on three types of CPU (silicon grease B for testing)

| | | | | Average | | |
|---|---|---|---|---|---|---|
| | Average | | Average | performance of | | |
| | performance | Average | performance | sample groups | | |
| | on the CPU | performance | on the CPU | on the CPU | | |
| | with slightly | on the CPU | with slightly | with three | Standard | |
| | concave | with high | convex | surface | deviation/ | Range/ |
| | surface /° C. | flatness/° C. | surface/° C. | forms/° C. | ° C. | ° C. |
| Flat base sample | 70.6 | 69.2 | 69.3 | 69.7 | 0.82 | 1.5 |
| group | | | | | | |
| Tapered convex | 69.6 | 68.9 | 71.8 | 70.1 | 1.49 | 2.9 |
| base sample group | | | | | | |
| Sample group with | 67.5 | 66.5 | 67.7 | 67.2 | 0.64 | 1.2 |
| Aₛₜₚ = 50 mm² in the | | | | | | |
| present invention. | | | | | | |

Secondly, considering the development trend of multi-core, multi-threaded, high-performance, and higher power density of the CPU core heating zone (DIE) of the CPU, the bottom region of the heat sink base corresponding to the CPU core heating zone (DIE) has been designed in a pioneering way to achieve lower thermal resistance and better cooling performance.

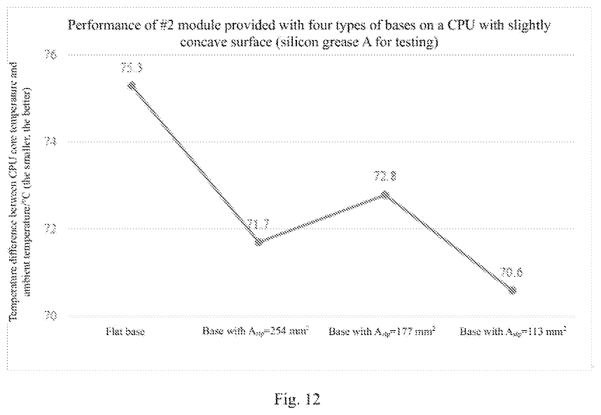

FIG. 12 shows the performance test data of the #2 heat pipe fin group provided with four types of bases on the CPU with slightly concave surface, these four bases are: a flat base, as well as the base with Aₛₜₚ=254 mm², the base with Aₛₜₚ=177 mm² and the base with Aₛₜₚ=113 mm² in the present invention. It can be known from the data that, on the CPU with slightly concave surface, the three types of bases with protruded structures 11 with gentle regions 111 all have better cooling efficiency than the flat base in the prior art.

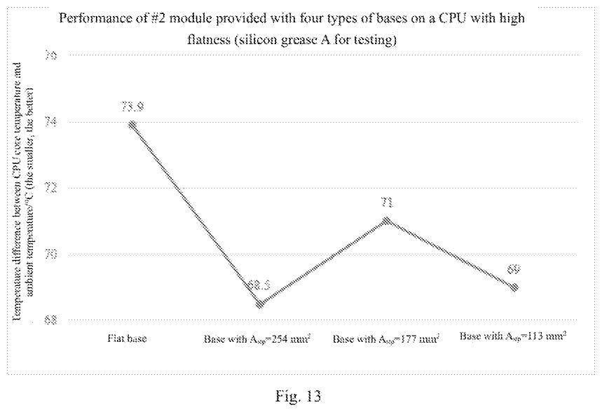

FIG. 13 shows the performance test data of the #2 heat pipe fin group provided with four types of bases on the CPU with high flatness. It can be known from the data that, on the CPU with high flatness, the three types of bases with protruded structures 11 with gentle regions 111 all have better cooling efficiency than the flat base in the prior art.

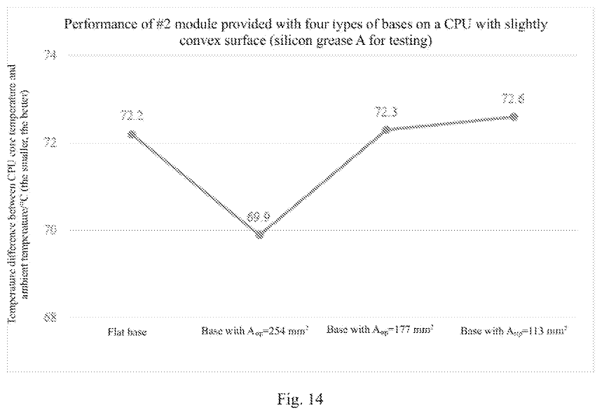

FIG. 14 shows the performance test data of the #2 heat pipe fin group provided with four types of bases on the CPU with slightly convex surface, it can be known from the data that, on the CPU with slightly convex surface, the base with Aₛₜₚ=254 mm² has better cooling efficiency than the flat base in the prior art.

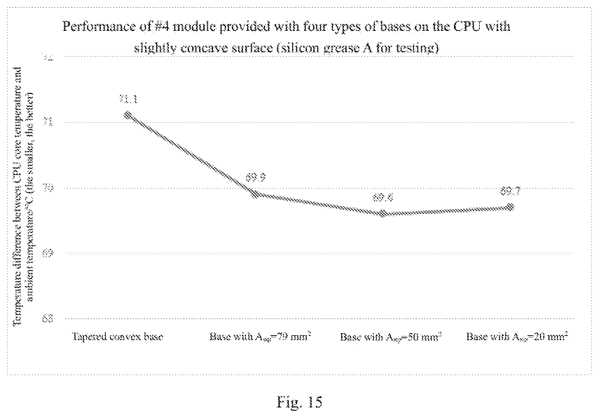

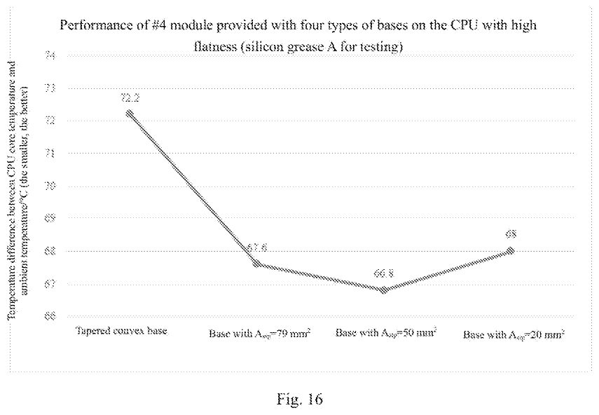

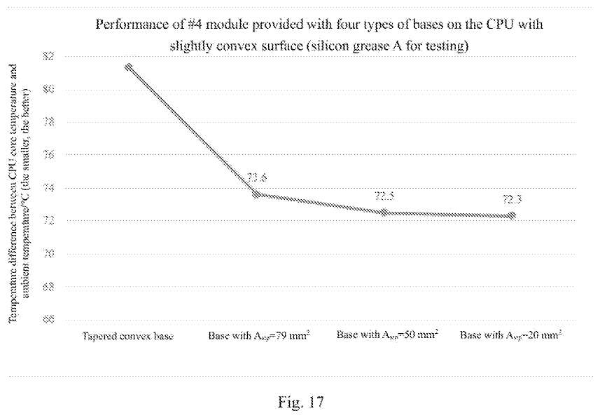

Similar to above, FIG. 15, FIG. 16 and FIG. 17 show the performance test data of the #4 module provided with four types of bases on the CPU with slightly concave surface, the CPU with high flatness, and the CPU with slightly convex surface, these four bases are: a tapered convex base, as well as the base with Aₛₜₚ=79 mm², the base with Aₛₜₚ=50 mm² and the base with Aₛₜₚ=20 mm² in the present invention. It can be known from the data that, on the CPU with three surface forms, the three types of bases with protruded structures 11 with gentle regions 111 all have better cooling efficiency than the tapered convex base in the prior art.

In conclusion, the bottom of the base body 1 is provided with at least one protruded structure 11. The protruded structure 11 includes a protruded gentle region 111 and a slope region 112, and entirely abuts against the surface of the CPU. The gentle region 111 of the protruded structure 11 has relatively high and relatively stable pressure compared with the slope region 112, and the number of the protruded structures is not limited in the present invention.

Moreover, in the electronic equipment cooling industry or other industries, as long as the cooling problem is involved, the structure of the base body 1 defined by the present invention can be used for the cooling of equipment, thereby greatly improving the cooling efficiency and the consistency and reliability of product performance.

In conclusion, the heat sink base and the heat sink provided by the present invention have a simple and reasonable structure, can better adapt to the CPU with different surface forms to reduce thermal contact resistance, can efficiently dissipate the heat generated by the CPU to improve the cooling efficiency, and can obtain more stable and more consistent cooling performance, thus greatly improving the reliability of the product.

The foregoing description of specific exemplary embodiments of the present invention is for illustrative and exemplary purposes. These descriptions are not intended to limit the present invention to the precise form disclosed, and apparently, many changes and variations may be made in accordance with the above teachings. The exemplary embodiments are chosen and described for the purpose of explaining the particular principles of the present invention and its practical application, thereby enabling those skilled in the art to implement and utilize a variety of different exemplary embodiments of the present invention, as well as a variety of different options and variations. The scope of the present invention is intended to be defined by the claims and their equivalent forms.

What is claimed is:

1. A heat sink base, comprising a base body, wherein the bottom of the base body is provided with at least one protruded structure, and the bottom of the base body abuts against the top of a CPU; each of the at least one protruded structure comprises a gentle region with a protrusion and a slope region located on the periphery of the gentle region;
the gentle region of the protruded structure abuts against a high heat flux region at the top of the CPU, thus forming a region with relatively high pressure and relatively stable pressure compared with the slope region.

2. The heat sink base according to claim 1, wherein the gentle region of the protruded structure is located on an internal region of the protruded structure, and a projection of the slope region is located on two sides, three sides, or the periphery of a projection of the gentle region.

3. The heat sink base according to claim 1, wherein the height of a geometric center point of the gentle region of the protruded structure is greater than or equal to that of the edge of the region, and on a contour line of either side of a horizontal direction of any profile passing through the geometric center point, an absolute value of a vertical height difference corresponding to a unit horizontal distance of any local range in the gentle region is smaller than an absolute value of a vertical height difference corresponding to a unit horizontal distance of any local range in the slope region.

4. The heat sink base according to claim 1, wherein the center of the gentle region of the protruded structure abuts against the center of the high heat flux region at the top of the CPU, thus forming a region with relatively high pressure and relatively stable pressure compared with the slope region.

5. The heat sink base according to claim 1, wherein the center of the gentle region of the protruded structure abuts against the position close to the center of the high heat flux region at the top of the CPU, thus forming a region with relatively high pressure and relatively stable pressure compared with the slope region.

6. The heat sink base according to claim 1, wherein the projection area of the gentle region of the protruded structure is smaller than the area of the top of the CPU.

7. The heat sink base according to claim 1, wherein a projection form of the gentle region of the protruded structure comprises: a circle, an ellipse or a polygon.

8. The heat sink base according to claim 1, wherein a profile counter line of a gentle region part of the protruded structure comprises: a straight line, an arc line or a broken line.

9. The heat sink base according to claim 1, wherein the area of the gentle region of the protruded structure is 20 mm² to 254 mm².

10. The heat sink base according to claim 1, wherein the area of the gentle region of the protruded structure is 20 mm² to 177 mm².

11. The heat sink base according to claim 1, wherein the area of the gentle region of the protruded structure is 20 mm² to 113 mm².

12. The heat sink base according to claim 1, wherein the area of the gentle region of the protruded structure is 20 mm² to 79 mm².

13. The heat sink base according to claim 1, wherein the area of the gentle region of the protruded structure is 20 mm² to 50 mm².

14. A heat sink for cooling a CPU, comprising a base body, wherein the bottom of the base body is provided with at least one protruded structure, and the bottom of the base body abuts against the top of a CPU; each of the at least one protruded structure comprises a gentle region with a protrusion and a slope region located on the periphery of the gentle region;
the gentle region of the protruded structure abuts against a high heat flux region at the top of the CPU, thus forming a region with relatively high pressure and relatively stable pressure compared with the slope region.

15. The heat sink according to claim 14, wherein the gentle region of the protruded structure is located on an internal region of the protruded structure, and a projection of the slope region is located on two sides, three sides or the periphery of a projection of the gentle region.

16. The heat sink according to claim 14, wherein the height of a geometric center point of the gentle region of the protruded structure is greater than or equal to that of the edge of the region, and on a contour line of either side of a horizontal direction of any profile passing through the geometric center point, an absolute value of a vertical height difference corresponding to a unit horizontal distance of any local range in the gentle region is smaller than an absolute value of a vertical height difference corresponding to a unit horizontal distance of any local range in the slope region.

17. The heat sink according to claim 14, wherein the center of the gentle region of the protruded structure abuts against the center of the high heat flux region at the top of the CPU, thus forming a region with relatively high pressure and relatively stable pressure compared with the slope region.

18. The heat sink according to claim 14, wherein the center of the gentle region of the protruded structure abuts against the position close to the center of the high heat flux region at the top of the CPU, thus forming a region with relatively high pressure and relatively stable pressure compared with the slope region.

19. The heat sink according to claim 14, wherein a projection form of the gentle region of the protruded structure comprises: a circle, an ellipse, or a polygon.

20. The heat sink according to claim 14, wherein a profile contour line of a gentle region part of the protruded structure comprises: a straight line, an are line, or a broken line.

21. The heat sink according to claim 14, wherein the projection area of the gentle region of the protruded structure is smaller than the area of the top of the CPU.

22. The heat sink according to claim 14, wherein the area of the gentle region of the protruded structure is 20 mm² to 254 mm².

23. The heat sink according to claim 14, wherein the area of the gentle region of the protruded structure is 20 mm² to 50 mm².

24. The heat sink according to claim 14, further comprising:
a cooling fin group, arranged at one end away from the base body:
a heat pipe group, comprising at least one heat pipe, wherein the heat pipe comprises a heat adsorption section and a cooling section, the heat adsorption section is arranged on the base body, and the cooling section is arranged in the cooling fin group; and
a fixing assembly, configured to fix the base body to the position above the CPU.

25. The heat sink according to claim 14, further comprising:
a cooling part, provided with a water inlet and a water outlet;
a heat adsorption part, provided with a water inlet and a water outlet, wherein a water pump is arranged inside the heat adsorption part, and the heat adsorption part is arranged on one end of the base body; and
a pipeline part, comprising a first pipeline and a second pipeline, wherein one end of the first pipeline and one end of the second pipeline are connected to the water inlet and the water outlet of the cooling part, respectively; and the other end of the first pipeline and the other end of the second pipeline are connected to the water outlet and the water inlet of the heat adsorption part, respectively; and under the action of the water pump, cooling liquid circulates among the cooling part, the pipeline part and the heat absorption part.
